(19) United States
(12) Patent Application Publication
(10) Pub. No.: US 2009/0027119 A1
(43) Pub. Date: Jan. 29, 2009

(54) Reduced distortion radio frequency amplifiers

(75) Inventors: Bertrand Jeffery Williams, Austin, TX (US); Kelly Mekechuk, Austin, TX (US); Thomas Johnson, Austin, TX (US); Dan Huslig, Dripping Springs, TX (US)

Correspondence Address: LAW OFFICES OF CHARLES W. BETHARDS, LLP, P.O. BOX 1622, COLLEYVILLE, TX, 76034, US

(73) Assignee: PulseWave RF, Inc.

(21) Appl. No.: 12/220,594

(22) Filed: Jul. 25, 2008

Related U.S. Application Data
(60) Provisional application No. 60/961,945, filed on Jul. 25, 2007.

(51) Int. Cl. H03F 1/26

(52) U.S. Cl. 330/149; 330/136

(57) ABSTRACT

A radio frequency power amplifier system includes a power amplifier coupled to an input signal and configured to provide an output signal at a radio frequency; a signal cancellation system coupled to the input signal, and a first feedback signal, which is based on the output signal, and configured to provide an error signal with a reduced level of the input signal; and a feedback control system coupled to the error signal and configured to provide a correction signal that is used to reduce distortion in the output signal. A corresponding method includes amplifying in a forward path an input signal to provide an output signal at a radio frequency; combining a reference and a first feedback signal to provide an error signal with a reduced level of the input signal; providing, responsive to the error signal and in a. feedback control system that is separate from the forward path, a correction signal; and then using the correction signal to reduce distortion in the output signal.

### RELATED APPLICATIONS

This application is related to and claims priority from Provisional Application bearing Ser. No. 60/961,945, filed Jul. 25, 2007, titled REDUCED DISTORTION RADIO FREQUENCY AMPLIFIERS, by INVENTORS: BERTRAND JEFFERY WILLIAMS; KELLY MEKECHUK; THOMAS JOHNSON; DAN HUSLIG, which application is incorporated herein in its entirety by reference.

### FIELD OF THE INVENTION

This invention relates in general to radio frequency power amplifier apparatus and methods and more specifically to techniques and apparatus for reducing distortion in radio frequency power amplifiers.

### BACKGROUND OF THE INVENTION

Radio frequency power amplifiers are known and various classes, from linear to hard switching classes, of such amplifiers have been utilized. All of these amplifiers have tradeoffs between linearity, efficiency, and economic considerations. Generally, linearity comes at the cost of efficiency.

One recently develop power amplifier system is shown in FIG. 8. In FIG. 8 a feedback approach is used, where the input signal and a feedback signal are combined with the feedback control system processing a combination of the input signal and the feedback signal. This can burden the feedback control system in terms of required dynamic range.

Additionally, the quantization noise, largely out of band for the system of FIG. 8 can be higher than desirable and this can burden the power amplifier, since a portion of its dynamic range is devoted to out of band power generation.

Feed forward radio frequency power amplifiers, such as shown in FIG. 10 have been used wherein an error signal based on the difference between a power amplifier output signal and the input signal is fed forward and used to cancel the distortion. These systems are notoriously inefficient, difficult to align so as to operate effectively, difficult to maintain alignment over environmental variables, and can be expensive.

### BRIEF DESCRIPTION OF THE DRAWINGS

The accompanying figures where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 depicts in a simplified and representative form, a high level diagram of a radio frequency power amplifier system with reduced distortion in accordance with one or more embodiments;

FIG. 2 in a representative form, shows a more detailed embodiment of a reduced distortion radio frequency power amplifier using principles in accordance with FIG. 1;

FIG. 3 depicts a representative diagram of a feedback control system suitable for use in the FIG. 1 or FIG. 2, among others, radio frequency power amplifiers in accordance with one or more embodiments;

FIG. 4A-4B depicts diagrams of a representative correction signal from the FIG. 3 feedback control system and an exemplary input signal;

FIG. 5 depicts a representative power amplifier output spectrum with and without the feedback control system of FIG. 3;

FIG. 6A-6D illustrates representative signal spectrums observed in simulation results at various points in the FIG. 2 embodiment;

FIG. 7 shows experimental results for the radio frequency amplifier of FIG. 2 with and without the feedback control system of FIG. 3;

FIG. 8 shows a block diagram of a prior art radio frequency power amplifier;

FIG. 9 shows a comparison of output spectrums for simulations of the amplifier embodiment of FIG. 2 and FIG. 8;

FIG. 10 shows a prior art feed forward power amplifier;

FIG. 11 shows a representative block diagram of a reduced distortion radio frequency power amplifier similar to the system of FIG. 1 but illustrates one or more alternative embodiments to that shown in FIG. 2;

FIG. 12 illustrates a representative block diagram of reduced distortion radio frequency power amplifier employing a predistorter and the feedback control system in accordance with one or more embodiments;

FIG. 13 depicts a representative block diagram of reduced distortion radio frequency power amplifier employing a controlled supply and the feedback control system in accordance with one or more embodiments;

FIG. 14 depicts an alternative feedback control system employing a synchronous sequencer in accordance with one or more embodiments;

FIG. 15 shows a representative block diagram showing additional power amplifiers and feedback control systems in accordance with one or more embodiments; and

FIG. 16 shows a flow chart illustrating representative embodiments of methods of reducing distortion in a radio frequency power amplifier system.

### DETAILED DESCRIPTION

In overview, the present disclosure concerns radio frequency power amplifiers and more specifically techniques and apparatus, in radio frequency power amplifiers, that are arranged and constructed for separating an input signal from a feedback signal to provide a correction signal that is used to reduce distortion generated by the radio frequency power amplifier will be discussed and disclosed.

The radio frequency power amplifiers that are of interest may vary widely but include such amplifiers used for wireless transmitters, e.g., Base station Transmitter Systems, in Cellular Phone Systems, dispatch systems, broadcast systems, or other public or private radio access networks and the like.

The instant disclosure is provided to further explain in an enabling fashion the best modes, at the time of the application, of making and using various embodiments in accordance with the present invention. The disclosure is further offered to enhance an understanding of and appreciation for the inventive principles and advantages thereof, rather than to limit in any manner the invention. The invention is defined solely by the appended claims including any amendments made during the pendency of this application and all equivalents of those claims as issued.

It is further understood that the use of relational terms, if any, such as first and second, top and bottom, and the like are used solely to distinguish one from another entity or action without necessarily requiring or implying any actual such relationship or order between such entities or actions.

Much of the inventive functionality and many of the inventive principles are best implemented with or in integrated circuits (ICs) including possibly application specific ICs or ICs with integrated processing controlled by embedded software or firmware. It is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation. Therefore, in the interest of brevity and minimization of any risk of obscuring the principles and concepts according to the present invention, further discussion of such software and ICs, if any, will be limited to the essentials with respect to the principles and concepts of the various embodiments.

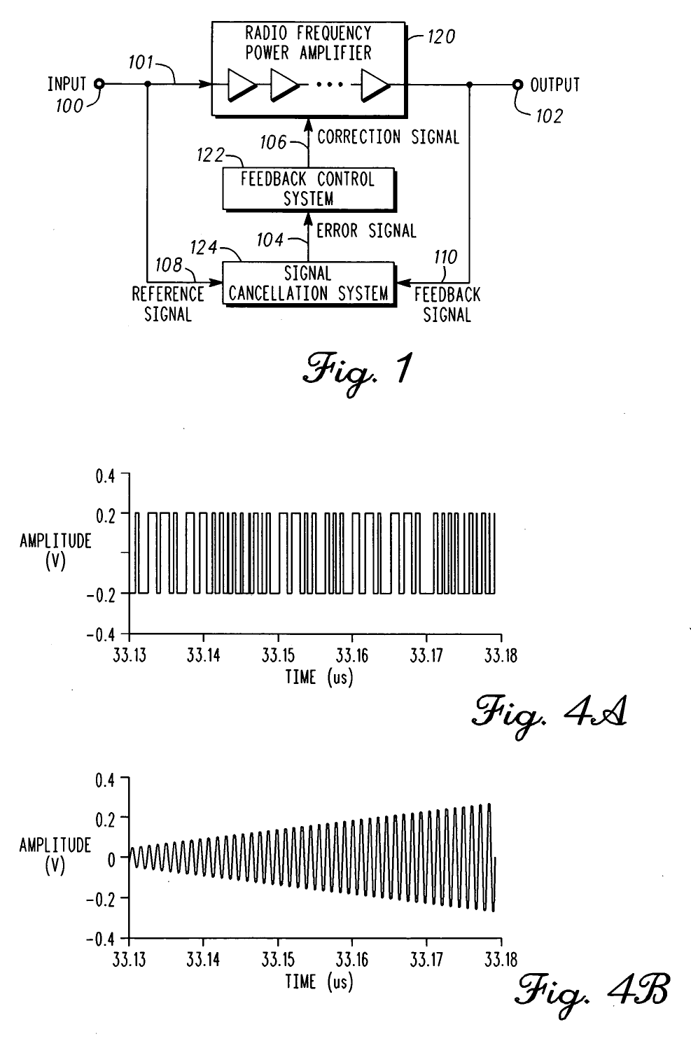

Referring to FIG. 1, a simplified and representative high level diagram of a radio frequency power amplifier system with reduced distortion in accordance with one or more embodiments will be briefly discussed and described. The FIG. 1 diagram will be used to discuss and describe various methods and apparatus to reduce distortion in a radio frequency power amplifier. Throughout the following discussions reference numerals may be used to refer to a physical element as well as to signals and the like that can be present at that element, e.g., an output 102 may refer to an output signal at that output or to the actual physical output, where the context can generally be used to distinguish one from the other.

The general block diagram of a power amplifier system with reduced distortion of FIG. 1 includes three main elements: 1) a radio frequency power amplifier 120, 2) a feedback control system 122, and 3) a signal cancellation system 124 all inter coupled as illustrated. The power amplifier 120 or radio frequency power amplifier has an output signal 102 greater than its input signal 100, specifically 101, and, during the amplification process, the power amplifier typically adds or creates distortion (often referred to as native distortion) due to various non-linearity's of the power amplifier, which appears in the output signal. The power amplifier system of FIG. 1 can and is arranged and configured to reduce the native distortion which can be generated by the power amplifier and which would otherwise be present in the output signal 102.

The distortion in or generated by the power amplifier 120 is reduced by injecting a correction signal 106 generated by the feedback control system 122 into the signal path of the power amplifier 120. A feedback loop is created by signal flow from the output signal 102, through the signal cancellation system 124, through the feedback control system 122, and then back to the output 102 through the power amplifier 120. One or more embodiments of the feedback control system 122, or portions thereof, are similar to various systems and the like described in pending patent applications with Ser. No. 11/089,834, filed Mar. 25, 2005, now U.S. Pat. No. 7,352,237, issued Apr. 1, 2008, titled RADIO FREQUENCY POWER AMPLIFIER AND CORRESPONDING METHOD by inventors, WILLIAM MARTIN SNELGROVE, KELLY MEKECHUK, DAVID KELLY, RICHARD WILSON; Ser. No. 11/413,998, filed Apr. 28, 2006, titled RADIO FREQUENCY POWER AMPLIFIER AND METHOD USING A PLURALITY OF FEEDBACK SYSTEMS by inventors, KELLY MEKECHUK, WILLIAM MARTIN SNELGROVE; Ser. No. 11/413,999, filed Apr. 28, 2006, titled RADIO FREQUENCY POWER AMPLIFIER AND METHOD USING AN AMPLITUDE CONTROL SYSTEM by inventors, WILLIAM MARTIN SNELGROVE, DAVID LOVELACE, RICHARD WILSON, KELLY MEKECHUN, THOMAS A. BLEASE, Jr; and Ser. No. 11/818,925, filed Jun. 15, 2007, titled RADIO FREQUENCY POWER AMPLIFIER AND METHOD USING A CONTROLLED SUPPLY by inventors, WILLIAM MARTIN SNELGROVE, KELLY MEKECHUK, each of which is hereby included in their entirety by reference.

The input to the feedback control system is an error signal 104, which is the output of the signal cancellation system 124. The signal cancellation system will control the level of the desired or input signal, i.e., reference signal 108 (corresponds to or is based on the input signal 100), which is removed from the feedback signal 110. In one or more embodiments of the signal cancellation system 124, the amplitude and phase of the feedback signal 110 and reference signal 108 are appropriately conditioned to generate the required input signal attenuation or level reduction in the error signal 104.

The signal cancellation system uses two signals at its inputs; the reference signal 108 which is or corresponds to or is based on the input signal 100 and the feedback signal 110, which is or corresponds to or is based on the output signal 102 from the power amplifier system, to control the cancellation or reduction in level of the desired or reference signal or input signal component in the feedback signal 110. The output error signal 104 from the signal cancellation system is therefore similar to the feedback input signal 110 except for a reduction in amplitude of the desired or input signal components. Usually the signal cancellation system is aligned to generate an error signal 104 which primarily consists of residual distortion in the amplifier output signal. However, it may in certain embodiments be advantageous or appropriate to adjust the signal cancellation system to reduce, e.g., to a predetermined level, rather than fully attenuate, the desired signal components in the feedback signal. For example, in some embodiments it is appropriate to reduce the level of the input or desired signal to a predetermined level and then use the feedback control system to add or subtract the amount of desired or input signal in the correction signal. This helps to compensate for imperfect signal cancelation systems or allows for the use of more economically attractive cancellation systems and devices.

FIG. 1 and these discussions illustrate and have described a radio frequency power amplifier system comprising a radio frequency power amplifier 120 having an input 101 coupled to an input signal 100 and configured to provide an output signal at 102, which is at a radio frequency and reasonably high power levels. The power amplifier 120 as suggested by FIG. 1 can have a multiplicity of gain stages and some of these can include parallel gain stages as known. Further shown is a signal cancellation system which is coupled to a reference signal 108, where the reference signal corresponds to or is based on or is possibly equivalent to the input signal 100. The signal cancellation system is also coupled to a first feedback signal 110, which is based on or corresponds to the output signal. The signal cancellation system is arranged and configured to provide an error signal 104, where the error signal has a reduced level of the input signal. The signal cancellation system essentially reduces the level of the reference signal, i.e., input signal 100, which is present in the output signal and provides the result as the error signal 104. The radio frequency power amplifier further includes a feedback control system 122 that is coupled to the error signal and configured to provide a correction signal 106, where the correction signal is used to reduce distortion in the output signal. Various embodiments of the feedback control system and their uses to reduce distortion will be described herein below.

Referring to FIG. 2, a representative but more detailed embodiment of a reduced distortion radio frequency power amplifier system using principles in accordance with FIG. 1 will be discussed and described. In the exemplary embodiment of FIG. 2, the signal cancellation system is implemented with three signal adjuster functions or blocks (signal adjusters 202, 204, 206) and a signal combiner 212. Signal adjuster A 202 adjusts the input signal (level and phase) and signal adjuster C 206 adjusts the level of the feedback signal. These signal adjusters 202, 204, 206 can be used to align the phase and amplitude of the feedback signal 230 such that the signal component or desired component in the feedback signal 230 (output signal 232 as adjusted by 206) is reduced at the output 214 of the signal combiner 212 (i.e., in the error signal 214). This can be done in an experimental manner or otherwise. The combiner 212 cancels essentially all or a predetermined portion of the input signal component that would otherwise be in the error signal. In some embodiments the signal cancellation system is configured to provide the error signal with a predetermined level of the input signal. Thus, the signal cancellation system is comprised of signal adjusters that adjust the amplitude and phase of the feedback signal or the amplitude or phase of the reference signal, such that the level of the input signal in the error signal is reduced appropriately.

After signal cancellation, the error signal 214 is primarily residual distortion which the feedback control system 238 uses to synthesize a correction signal 240 for the power amplifier 220. The correction signal 240 is summed with the signal adjuster A output signal 241 to form an amplifier input signal 244 to the power amplifier 220. After amplification this is provided at output 102 and as an input signal 232 to adjuster 206. Thus FIG. 2 illustrates an embodiment where the correction signal and the input signal as adjusted are coupled to the input 244 of the radio frequency power amplifier 220.

Signal adjuster B (204), e.g., a delay line, is used to improve the bandwidth of the signal cancellation in the feedback loop. The delay line compensates for the delay of the desired signal component as it passes through signal adjuster A (202), the power amplifier (220), and signal adjuster C (206) connecting to the feedback input port 230 of the signal combiner 212. Signal adjusters A, B, C and there respective functions are generally known.

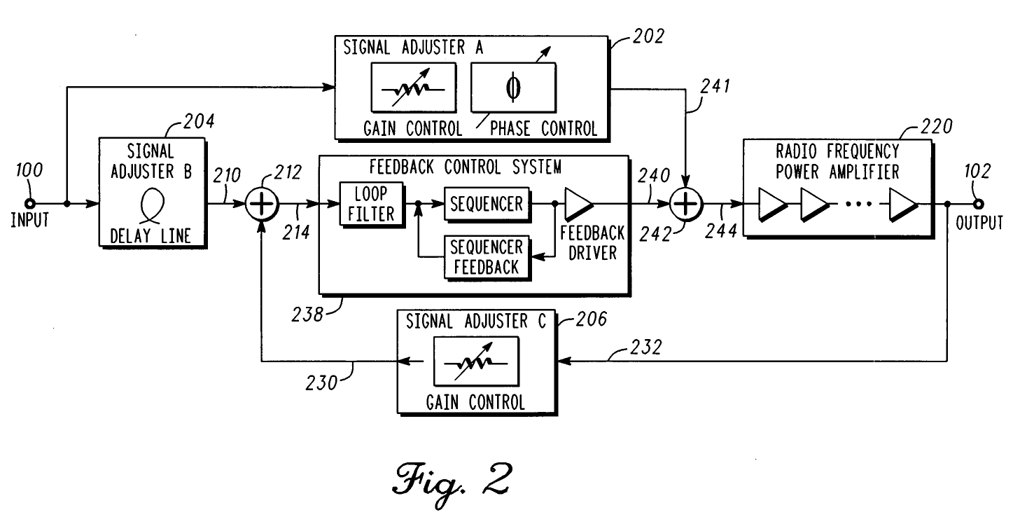

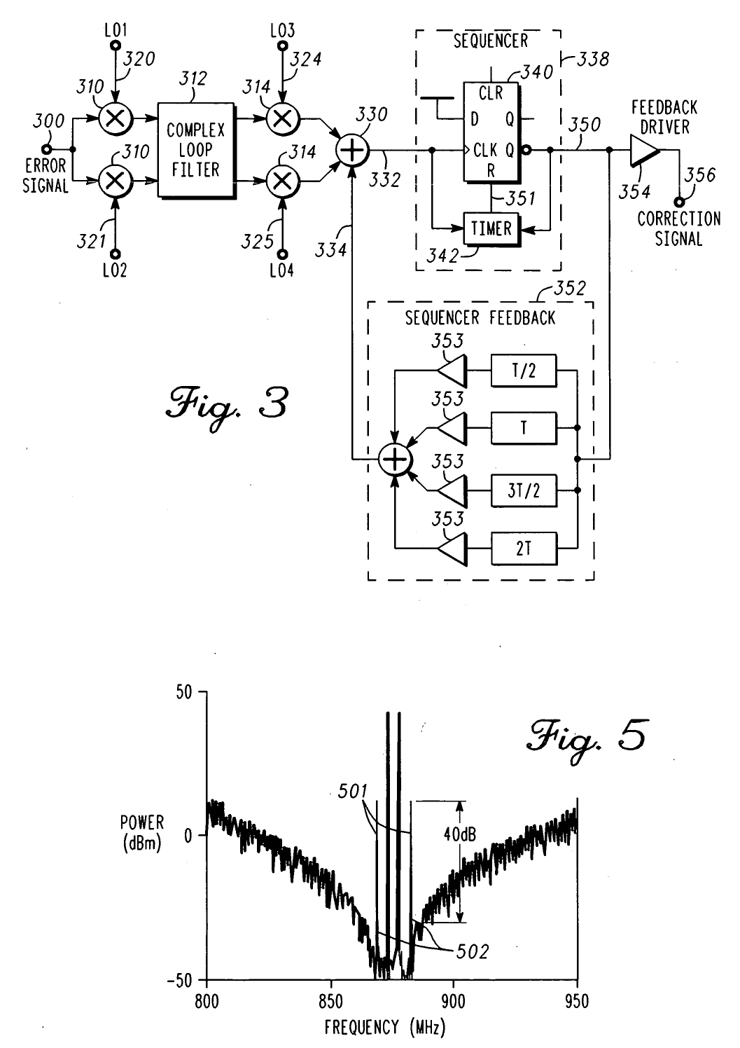

Referring to FIG. 3, a representative diagram of a feedback control system suitable for use in the FIG. 1 or FIG. 2 radio frequency power amplifier systems, among others, in accordance with one or more embodiments will be discussed and described. The feedback control system in FIG. 3 includes, among others, a loop filter 312 and a sequencer 338 and is arranged and constructed to synthesize a quantized, e.g., two level quantized amplitude, correction signal 356 (supplied by feedback driver 354) with, in some embodiments variable pulse widths from an input error signal 300. The amplitude quantized correction signal leads to a robust feedback system that may otherwise be more difficult to implement. An example of a typical correction signal generated by the feedback control system is shown in FIG. 4A. It will be observed that the correction signal comprises a waveform with quantized amplitude occurring at an average frequency in accordance with or equivalent to the radio frequency of the output signal with timing (pulse widths or zero crossings) determined by the feedback control system.

With reference again to FIG. 2, the amplitude quantized correction signal 240 (analogous to correction signal 356) is combined with a signal 241, i.e., the input signal 100, as adjusted, from the output of signal adjuster A, to synthesize the amplifier input signal 244. FIG. 4B shows an example of signal 241 at the output of signal adjuster A.

Within the feedback control system of FIG. 3 there is a pair of down convert mixers 310 (complex mixers) which using local oscillators, LO1 320, LO2 321 translate the carrier frequency of the input error signal 300 to a complex intermediate frequency with in-phase and quadrature components. The intermediate frequency facilitates use of lower cost implementations of a highly selective complex bandpass filter or loop filter 312 (e.g., in one or more embodiment a fourth order bandpass filter with a bandwidth of 15 MHz and center frequency of approximately 40 MHz) to shape the error signal spectrum. After filtering, the signal is up converted using LO3 324, LO4 325, through a pair of mixers 314 and summed via combiner 330 to synthesize and provide a sequencer input signal 332.

The FIG. 2 radio frequency power amplifier system and feedback control system of FIG. 3 illustrates a system where the input signal 100 is a radio frequency signal at the radio frequency. It will be appreciated that the input signal could be a complex signal at a frequency which is different than the radio frequency, i.e. a complex baseband signal at a zero frequency carrier or a complex baseband signal with an intermediate frequency (IF) carrier. For ease of reference this will be referred to as a baseband signal or input baseband signal. In such cases, the feedback signal 230 would need to be down converted via complex mixers, similar to mixers 310, to form an intermediate complex feedback signal at the carrier frequency of the baseband signal, and combined with a complex combiner with the baseband signal with the output from the complex combiner applied directly to the complex loop filter 312. Similarly the baseband input signal would need to be up converted with complex mixers, similar to mixers 314, either before or after signal adjuster A 202. Thus, the radio frequency power amplifier system can operate with baseband input signals, e.g., by including complex mixers for frequency conversion of the input signal from a baseband frequency to the radio frequency and for frequency conversion of the feedback signal from the radio frequency to the baseband frequency.

An embodiment of a sequencer 338 as shown in FIG. 3 consists of a D flip-flop 340 and a timer 342. The sequencer embodiment of FIG. 3 is self clocked, i.e., is an asynchronous sequencer. The sequencer output state at 350 is normally high, and a rising edge zero-crossing on the sequencer input signal 332 changes the output state of the flip-flop or sequencer 350 from a high to low voltage, where the low output voltage condition can also be referred to as an off state. In some embodiments, the sequencer input signal 332 also connects to a timer 342. The timer is normally triggered by the high to low transition of the output state 350 and controls the reset input 351 of the flip-flop. The timer is typically set to generate an off state time for a preset time interval. The off state time interval is usually selected to(be approximately half the period of the carrier frequency of the radio frequency output signal from the power amplifier. After the timer expires, it generates an output signal 351 to reset the flip-flop which returns the flip-flop output 350 to a high state. The timer can be retriggered by subsequent rising edge zero-crossings at the sequencer input signal 332 which extend the off time to an interval longer than half the radio frequency carrier period.

The feedback control system may also include a sequencer feedback network or system 352 which can improve the performance of error correction depending, e.g., on the bandwidth and nonlinearity of the power amplifier. The sequencer feedback system or network 352 is arranged and configured to or for coupling a portion of the sequencer output 350 to the sequencer input 332 via the combiner 330. In the embodiment shown in FIG. 3, a transversal filter structure is employed in the sequencer feedback network 352 which consists of four branches with delays of T/2, T, 3T/2, and 2T, respectively, where T is the period of the radio frequency carrier. Each branch has an output weight 353 that determines the response of the sequencer feedback system.

Simulation and experimental results of the embodiment shown in FIG. 2 have been obtained for the feedback control system shown in FIG. 3. Simulations and corresponding results for the embodiment shown in FIG. 2 employing the feedback control system of FIG. 3 will be discussed.

A behavioral model of a power amplifier is used for the simulations which includes a nonlinear gain response. The input source signal 100 is two sinusoidal tones with frequencies of 873.15 MHz and 877.78 MHz. FIG. 5 depicts a representative power amplifier output spectrum illustrating the impact of the feedback control system of FIG. 3. The native distortion 501 of the power amplifier without any distortion correction is shown in FIG. 5 for the two tone source and the amplifier has a total output power of about 58 W. The figure shows the amplifier output signal in the frequency domain, and the native distortion, e.g., third order intermodulation products 501 are approximately −31 dBc (dB relative to carrier) relative to the desired signals. With the proposed distortion reduction apparatus and method, i.e., signal cancellation and feedback control systems of FIG. 2 and FIG. 3, which are configured to linearize the power amplifier, third order intermodulation products 502 are reduced to −73 dBc demonstrating a reduction in third order intermodulation of more than 40 dB.

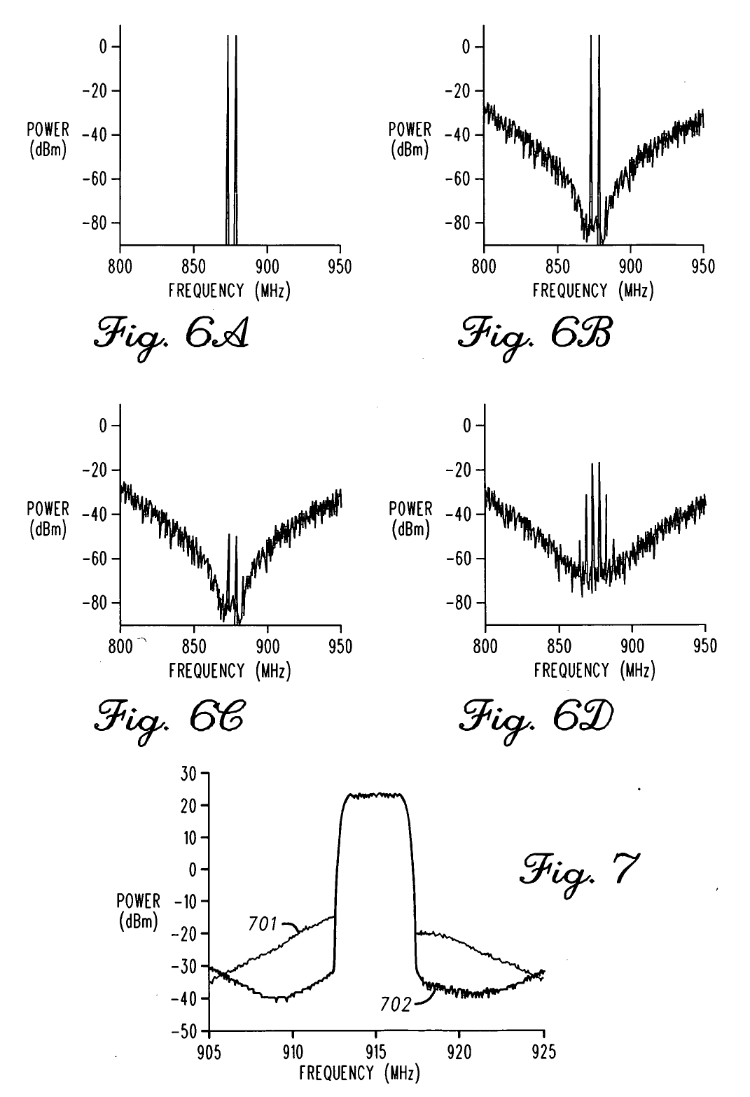

Examples of the corresponding reference signal 210, feedback signal 230, error signal 214 and correction signal 240 are shown in FIG. 6A-6D for the aforementioned simulation of the embodiment shown in FIG. 2 employing the feedback control system of FIG. 3. The signals in FIG. 6A-6D are shown in the frequency domain where the input signal is two sinusoidal tones with frequencies of 873.15 MHz and 877.78 MHz. The reference or input signal spectrum in FIG. 6A corresponds to the reference signal 210 or input signal 100 in FIG. 2. The spectrum consists of two tones free of any noise and distortion products over a dynamic range that exceeds 90 dB. The feedback signal spectrum in FIG. 6B corresponds to signal 230 in FIG. 2, and is similar to the amplifier output signal 102 in FIG. 2, except scaled in amplitude. The feedback spectrum shows third order intermodulation products which are less than −73 dBc relative to the desired signals and is similar to the amplifier output spectrum shown in FIG. 5. After the reference signal 210 and the feedback signal 230 are combined with appropriate signal adjuster settings to generate an error signal 214, the desired signal component in the error spectrum is reduced by signal cancellation. FIG. 6C shows the error signal spectrum, and compared with the feedback signal spectrum in FIG. 6B, the desired signal is reduced by more than 40 dB. The spectrum of the correction signal 240 generated by the feedback control system is shown in FIG. 6D. The correction signal 240 is then summed with the signal 241 in FIG. 2 to form the input signal 244 for the power amplifier.

Experimental results for a circuit employing the feedback control system in FIG. 3 in the embodiment of FIG. 2 are shown in FIG. 7. For this experiment, the source signal is a WCDMA (Wideband Code Division Multiple Access) modulated radio frequency carrier at a frequency of 915 MHz with a peak to average ratio of approximately 7.6 dB. The measured output power is 20 W for a power amplifier with a 1 dB compression point of approximately 110 W. The proposed method reduces signal distortion in the adjacent signal band by more than 15 dB compared to the spectrum of the amplifier without linearization. Trace 701 in FIG. 7 corresponds to the native distortion in the amplifier, while trace 702 corresponds to the amplifier response with linearization or distortion reduction.

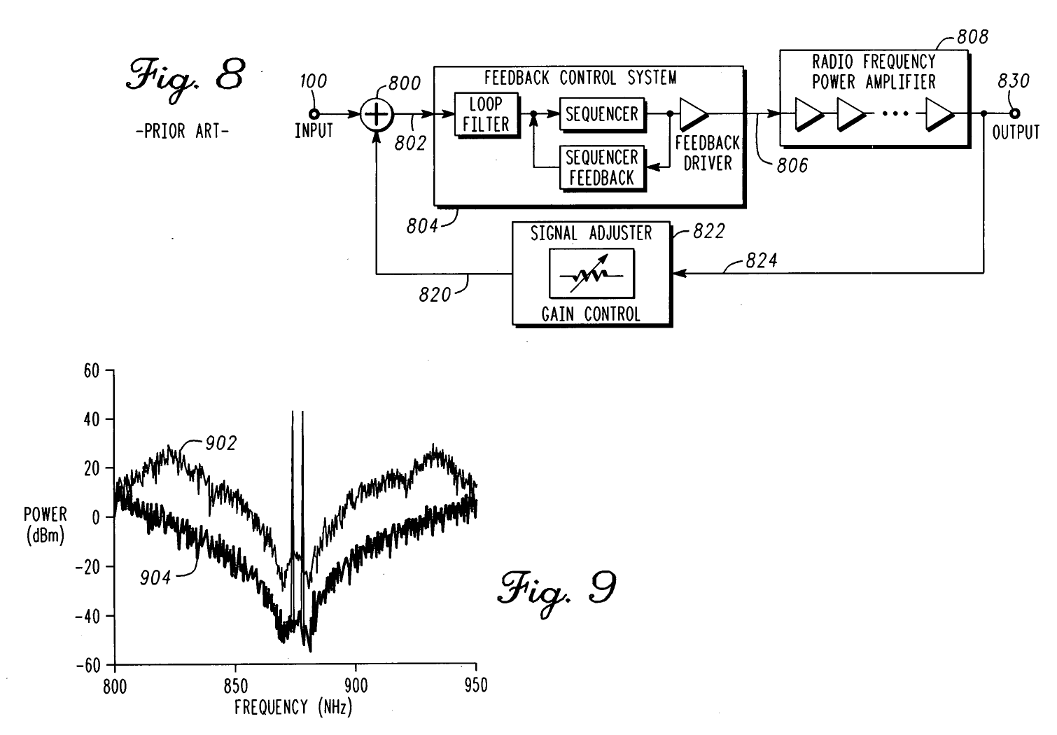

One distinction between the present approach for distortion reduction compared to other approaches is the addition of a signal cancellation system. The signal cancelation system operates to improve the dynamic range of error correction in the power amplifier system, specifically, the feedback control system. The difference between the proposed method and one other approach is illustrated by comparing an example approach, shown in FIG. 8 (also see one or more of the co-pending applications identified above), with the embodiment of the proposed method, in FIG. 2. In the FIG. 8 approach, the feedback control system 804 synthesizes a power amplifier input signal 806 which consists of both the desired input signal and a correction signal such that the power amplifier output signal 830 has reduced distortion. The power amplifier 808 output signal 830 produces an output feedback signal 824, which is level adjusted, via signal adjuster 822 to provide a feedback signal 820. Combiner 800 combines input signal 100 and the feedback signal to provide an error signal 802 (including distortion and input signal components) to the feedback control system. The disadvantage of generating both desired signal and correction signal components is the required dynamic range of the feedback control system. If distortion components are much smaller than the input or desired signal, a significant portion of the dynamic range of the feedback control system may be used for encoding the desired signal. In the proposed distortion reduction approach, the dynamic range overhead to encode signal power is reduced by providing a direct path from the input source or signal 100 to the amplifier input 244 and canceling all or much of the input signal component that is provided to the feedback control system. This direct path bypasses the feedback control system 238 as shown in FIG. 2.

The dynamic range enhancement of the proposed approach for correcting or reducing distortion compared to the FIG. 8 approach is illustrated further by comparing simulation results of two embodiments which have identical feedback control systems and power amplifier models. The embodiment in FIG. 8 is used with the feedback control system embodiment shown in FIG. 3 along with a behavioral model of a power amplifier. The distortion 902 (undesirable signal due to distortion, quantization noise, etc.) in the power amplifier output signal 830 is shown in FIG. 9. A second distortion 904 corresponding to output signal 102 is shown in FIG. 9 for a simulation of the proposed distortion reduction approach using the embodiment in FIG. 2 with the same feedback control system (FIG. 3) and the same power amplifier model.

The proposed approach clearly reduces noise and distortion in the noise well around the desired signals, which are two sinusoidal tones at of 873.15 MHz and 877.78 MHz. Broadband or out of band noise outside the noise well is also reduced significantly by more than 10 dB over a wide bandwidth. The reduction in out-of-band noise power relative to the desired signal power is significant. A high level of broadband noise may reduce power efficiency in the power amplifier system and limit the utilization of the devices in the power amplifier to deliver useful load power. For example, if half the output power is undesired broadband noise, then only half of the total power amplifier output power is transferred to the load. The addition of the signal cancellation system in the proposed method significantly improves the utilization of the total amplifier output power by increasing the ratio of signal power relative to broadband noise power. Consequently most of the output power is in the desired signal frequency spectrum and a small fraction of the total output power is broadband noise which can improve power efficiency and reduce costs of the power amplifier system.

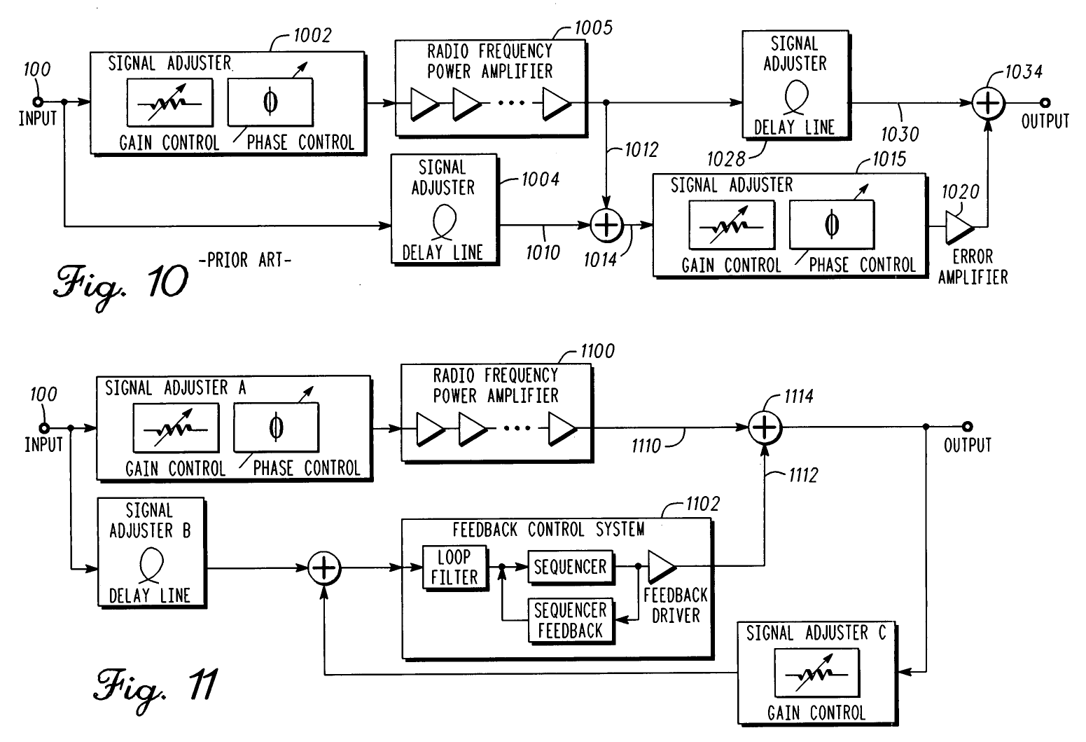

In known systems, such as feed forward power amplifiers, signal cancellation is employed to isolate distortion products from the desired signal at the output of the power amplifier. However, in the feed forward methods the residual error signal, after signal cancellation, is fed forward and summed, while in the proposed approach the residual error is fed back, conditioned by the feedback control system, and then summed. An example of a generally known feed forward amplifier system is shown in FIG. 10. Signal adjusters 1004, 1002 align the amplitude and phase of signals 1010 and power amplifier 1005 output signal 1012 such that the residual error signal 1014 is primarily distortion from the amplifier output signal. The distortion or error 1014 can be further adjusted via signal adjuster 1015 and is amplified by an error amplifier 1020 and then summed in anti-phase with the amplifier output signal 1030 by combiner or summer 1034 (typically a coupler) to cancel distortion. Feed forward power amplifiers also include an output delay line 1028 to match the delay of the error loop path. For high power amplifiers the delay line 1028 can be expensive and must remain stable over the operating temperature range of the amplifier, unlike the proposed method which avoids any requirement for a delay line in the feedback loop.

One clear difference between the prior art feed forward approaches and the proposed approach is this use of feedback. For example, a feedback system adapts in real time as a function of the output signal and can thus correct for errors in the signal cancellation system, while adaptation in a feed forward system is slow and there is no way to compensate for signal cancellation errors. For example, if signal cancellation is imperfect or varies over time and environmental factors, the feedback control system of FIG. 2 can add signal content to the correction signal to appropriately set or maintain the desired signal content in the error signal at the feedback control system input.

The embodiments described so far assume simple signal adjusters such as attenuators, phase shifters, or delay lines. More complex signal adjusters may be required for broadband signal cancellation. For example, if the amplifier has a gain slope relative to the reference path, then the gain slope limits the bandwidth of signal cancellation. For broadband applications, the signal adjusters may include an equalizer to compensate for gain slope and nonlinear phase responses. Such equalizers are generally known.

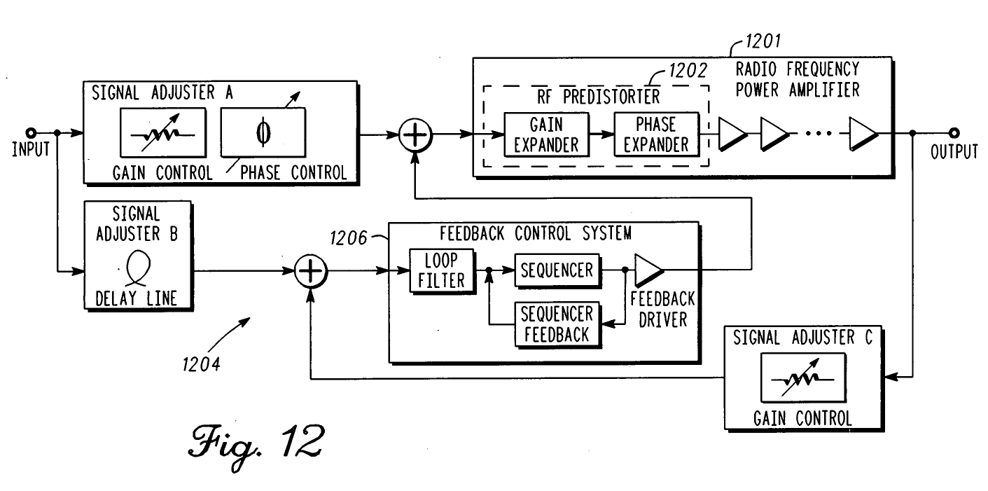

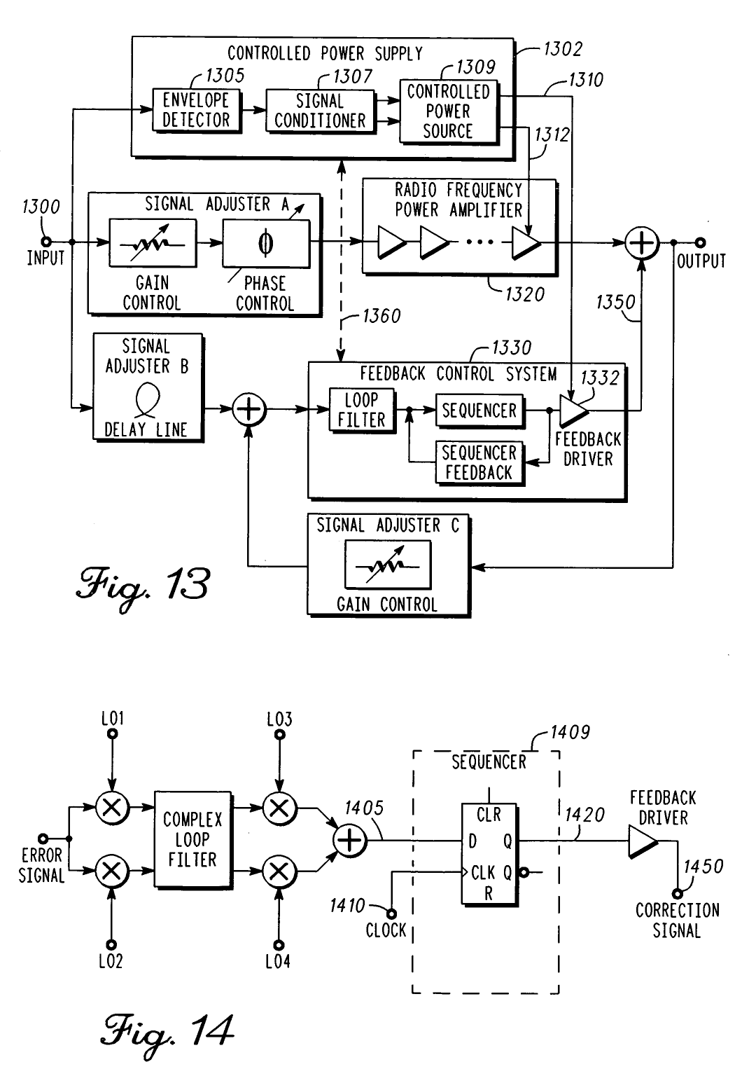

The embodiment of the distortion reduction approach or radio frequency power amplifier system in FIG. 2 shows a configuration where the correction signal and the input signal, as adjusted, at 241 is combined via combiner 242 at the input of the power amplifier, i.e., combiner 242 provides the input 244 to the power amplifier 220. Thus FIG. 2 (and FIG. 12—see below) illustrate embodiments of radio frequency power amplifier systems where the correction signal and the input signal are coupled to the input of the radio frequency power amplifier.

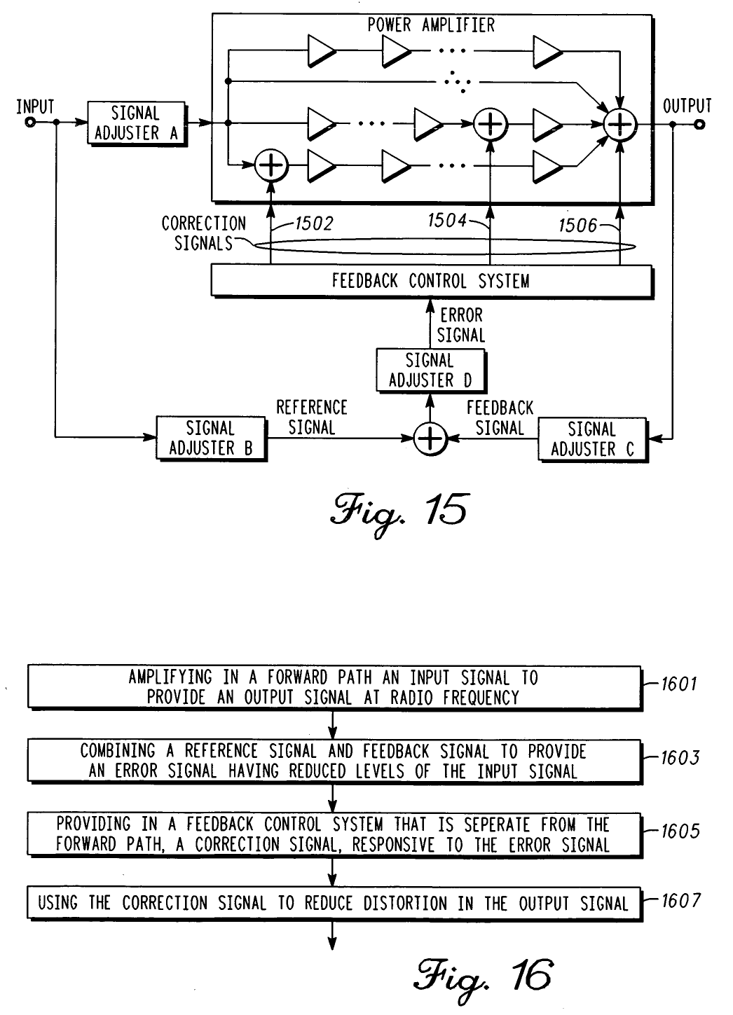

However, other embodiments of the radio frequency power amplifier system include configurations where the correction signal is combined either part way through the power amplifier (as suggested by FIG. 1 or FIG. 15 discussed below), or at the output of the amplifier as illustrated in FIG. 11 (and others below). The radio frequency power amplifier system of FIG. 11, where the distortion correction signal is combined with the power amplifier output signal at the output of the power amplifier will be described and discussed. FIG. 11 shows a radio frequency power amplifier system where the correction signal 1112 is applied at an output 1110 of the radio frequency power amplifier 1100 and thereby used to reduce distortion in the power amplifier output signal 1110. With reference to FIG. 11, the correction signal 1112 is combined via combiner or summing node 1114 (typically a coupler) with the power amplifier output signal 1110 and thus the signal out of the summing node will have lower distortion than the output signal 1110 of the power amplifier. In this embodiment, the summing node 1114 is similar to the summing node 1034 in a feed forward method as shown in FIG. 10; however, as described above, the correction signals are generated in completely different ways where the proposed method employs feedback, rather than feed forward summing.

An advantage of the embodiment shown in FIG. 11 is that the power amplifier 1100 is outside the feedback loop. Therefore, the design of the power amplifier is essentially independent of the design of the feedback control system 1102. In this configuration, the stability of the feedback loop is primarily a function of the feedback control system design and the feedback path. Thus, the power amplifier 1100 could be any type of design including but not limited to class A, AB, B, C, D, E, F, G, H or combinations thereof, e.g., AB and C or the like, or amplifiers with one or more power efficiency enhancements such as controlled supplies, predistorters, Doherty power amplifiers, or the like. When some or all of the power amplifier stages are included in the feedback loop such as the embodiment shown in FIG. 2, the amplifier characteristics must be consistent with a stable feedback loop, but this still does not exclude any particular class of power amplifier.

The distortion correction apparatus and methods described herein can be combined with other known distortion correction methods to increase the linearization range obtained with this approach. For example, the radio frequency power amplifier block 1201 can include an analog RF predistorter 1202 along with the radio frequency power amplifier as shown in FIG. 12. The predistorter 1202 can provide simple gain and phase compensation functions (expansion/compression—shown as expander functions in FIG. 12) to reduce distortion in the amplifier, and the feedback loop, i.e., signal cancellation (signal adjusters and combiner) 1204 and feedback control system 1206, then provides a further level of distortion reduction which, e.g., compensates for imperfect predistortion or allows for less expensive predistortion elements and the like.

Employing methods described in the pending U.S. patent application with Ser. No. 11/818,925, which is hereby included in its entirety, power efficiency of power amplifiers can be increased by adding a controlled power supply. The controlled power supply dynamically adjusts voltages in the power amplifier in accordance with a function depending typically on the input source signal 1300. Depending on the embodiment of the controlled power supply, described fully in patent application with Ser. No. 11/818,925, additional distortion errors may be generated in the power amplifier. Without an additional distortion correction system, the distortion errors introduced by the controlled power supply may be unacceptable. Therefore, if the controlled power supply is combined with the proposed distortion correction approach, additional distortion introduced by the controlled power supply are reduced by the feedback loop.

An embodiment of the distortion reduction approach with a controlled power supply is shown in FIG. 13. FIG. 13 illustrates a radio frequency power amplifier system that includes a controlled supply 1302 that is arranged and configured to provide power that is controlled in accordance with the input signal, wherein the power 1312 is provided to one or more stages of the radio frequency power amplifier 1320 and in some embodiments may provide control system power 1310 to portions of the feedback control system 1330, e.g., feedback driver 1332. The controlled power supply 1302 generates a time varying supply voltage 1312 which powers one or more stages in the power amplifier 1320 and in some instances a further time varying voltage 1310 which powers portions of the feedback control system.

The controlled power supply operates to increase the power efficiency of the overall power amplifier system. The controlled power supply 1302 dynamically adjusts the supply voltage 1312 in accordance with the envelope of the input signal 1300, or in accordance with a signal 1360 from the feedback control system 1330, or in accordance with input signals from both the input signal 1300 and feedback control system via signal 1360. Thus in some embodiments, the controlled supply is responsive to the feedback control system. With the controlled supply responsive to the feedback control system, the controlled supply no longer operates in an open loop mode with respect to the output of the power amplifier. The signal 1360 is an error signal (same as error signal at feedback control system input or derived by further processing) provided by the feedback control system and which results in the controlled supply becoming a portion of a closed loop vis-à-vis the power amplifier output to more appropriately control the power supplied at 1310, 1312. In various embodiments, the feedback control system can also be responsive to the controlled supply, e.g. level of power supplied can have an impact on phase delays or response of the power amplifier and thus appropriate phase of correction signals for distortion reduction or loop stability.

Within the controlled power supply 1302, there is an envelope detector 1305, signal conditioning circuitry 1307 (hysteresis, thresholds, filters, amplifiers, etc.) and a controlled power source 1309. An auxiliary output 1310 from the controlled power supply may be provided to power the feedback control system 1330, e.g., to power a portion of the control system 1330, for example, feedback driver 1332. The benefit of employing an auxiliary output signal 1310 is most significant in embodiments where the feedback driver sums a correction signal 1350 at the output of the power amplifier as shown in FIG. 13. If the correction signal is summed at the input of the power amplifier as shown in FIG. 2, the feedback driver is a relatively small low power consumption device and the improvement in overall power efficiency of the amplifier system may be small if a controlled power supply is used to power the feedback driver.

While one or more embodiments of the feedback control system include a loop filter with an asynchronous sequencer as shown in FIG. 3, other embodiments of feedback control systems can utilize synchronous sequencers in the feedback control system. For example, a continuous-time (i.e., continuous time loop filter) sigma delta modulator shown in FIG. 14 could be used as a feedback control system for the error correction or distortion reduction system. The sequencer 1409 has a synchronous clock input 1410 which samples the sequencer input signal 1405. The output signal 1420 from the sequencer is latched high or low depending on whether the input is high or low at the time of the clock edges. The output signal 1420 is provided to the feedback driver which provides the correction signal 1450. Thus FIG. 14 in conjunction with various other FIGs, illustrates a radio frequency power amplifier system with a feedback control system that includes a synchronous (clocked) sequencer 1409, which is clocked from an external clock. While not specifically depicted it will be appreciated that the synchronous sequencer can also use a sequencer feedback system, e.g., similar to feedback system 352 as illustrated in and discussed with reference to FIG. 3. One advantage of employing asynchronous sequencers as in FIG. 3 instead of synchronous sequencers in the feedback control system is that the asynchronous sequencer can generate correction signals with an average transition rate that is similar to the carrier frequency of the output signal while maintaining efficient coding.

Examples of other embodiments of a radio frequency power amplifier system are shown in FIG. 15. As shown in FIG. 15, the power amplifier may consist of one or more parallel branches where each branch may have one or more stages. The correction signal generated by the feedback control system may be connected to the input 1502 of the first stage of a branch in the power amplifier and is similar to the embodiment described above in FIG. 2. In other embodiments, the correction signal could be combined at the input of a stage part way through the amplifier as shown by input 1504. Or, as shown by input 1506, the correction signal could be combined at the output of a final stage in the power amplifier.

Referring to FIG. 16 a representative flow chart illustrating various methods of reducing distortion in a radio frequency power amplifier system in accordance with one or more embodiments will be discussed and described. It will be appreciated that this method uses many of the inventive concepts and principles discussed in detail above and thus this description will be somewhat in the nature of a summary with various details generally available in the earlier descriptions. This method can be implemented in one or more of the structures or apparatus described earlier or other similarly configured and arranged structures.

The flow chart of FIG. 16 begins with amplifying in a forward path an input signal in a radio frequency power amplifier to provide an output signal at a radio frequency 1601, where it will be appreciated that one or more of the various power amplifier embodiments and modifications noted above can be used for the amplifying process. Next the method includes 1603 combining a reference signal that is based on the input signal and a first feedback signal that is based on the output signal to provide an error signal, the error signal having a reduced level of the input signal. The combining a reference signal and a first feedback signal can comprise adjusting the phase and amplitude of the reference signal or the first feedback signal to reduce a level of the input signal that is present in the error signal. Generally after reduction of the input signal, the error signal will be largely residual distortion of the output signal from the power amplifier. This adjusting can be done with signal adjusters as discussed above so that the level of the input signal is at a predetermined level.

The method then includes providing or generating or synthesizing, in a feedback control system that is separate from the forward path, a correction signal, responsive to the error signal 1605. The correction signal in various embodiments is an amplitude quantized correction signal with an average frequency in accordance with the radio frequency and with timing or zero crossings or phase determined by the feedback control system. Next 1607, illustrates using the correction signal to reduce distortion in the output signal. Given the correction signal, it can be coupled to an input of the radio frequency power amplifier along with the input signal and thereby reduce distortion at the output. In other embodiments, the correction signal can be coupled to an output of the radio frequency power amplifier and used to reduce or cancel distortion. The method can be repeated as necessary or in practice is a continually running method.

The processes, apparatus, and systems, discussed above, and the inventive principles thereof are intended to and can alleviate issues caused by prior art techniques, such as insufficient dynamic range of the feedback control system or excess out of band power generation or the setup and stability problems associated with feed forward power amplifiers.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

1. A radio frequency power amplifier system comprising:
a radio frequency power amplifier having an input coupled to an input signal and configured to provide an output signal at a radio frequency;
a signal cancellation system coupled to a reference signal, which is based on the input signal, and a first feedback signal, which is based on the output signal, and configured to provide an error signal, the error signal having a reduced level of the input signal; and
a feedback control system coupled to the error signal and configured to provide a correction signal, the correction signal used to reduce distortion in the output signal.

2. The radio frequency power amplifier system of claim 1, wherein the correction signal comprises a waveform occurring at an average frequency in accordance with the radio frequency with timing determined by the feedback control system.

3. The radio frequency power amplifier system of claim 1 further comprising:
a controlled supply configured to provide power that is controlled in accordance with the input signal, wherein the power is provided to one or more stages of the radio frequency power amplifier.

4. The radio frequency power amplifier system of claim 3, wherein the controlled supply is further configured to provide control system power to one or more stages of the feedback control system.

5. The radio frequency power amplifier system of claim 3, wherein the feedback control system is responsive to the controlled supply.

6. The radio frequency power amplifier system of claim 3, wherein the controlled supply is responsive to the feedback control system.

7. The radio frequency power amplifier system of claim 1 wherein the correction signal and the input signal are coupled to the input of the radio frequency power amplifier.

8. The radio frequency power amplifier system of claim 1 wherein the correction signal is applied at an output of the radio frequency power amplifier and thereby used to reduce distortion in the output signal.

9. The radio frequency power amplifier system of claim 1 wherein the radio frequency power amplifier is one or more of a class A, AB, B, C, D, E, F, G, and H radio frequency power amplifier.

10. The radio frequency power amplifier system of claim 1 wherein the radio frequency power amplifier further comprises one or more power efficiency enhancements.

11. The radio frequency power amplifier system of claim 10 wherein the one or more power efficiency enhancements includes one or more of a Doherty power amplifier, a controlled supply, and a predistorter.

12. The radio frequency power amplifier system of claim 1 wherein the signal cancellation system is comprised of a first signal adjuster to adjust the amplitude and phase of the first feedback signal, and a second signal adjuster to adjust the amplitude and phase of the reference signal.

13. The radio frequency power amplifier system of claim 12 wherein the first signal adjuster and the second signal adjuster are configured to reduce a level corresponding to the input signal that is in the error signal to a predetermined level.

14. The radio frequency power amplifier system of claim 1 wherein the feedback control system is comprised of a loop filter and a sequencer.

15. The radio frequency power amplifier system of claim 14 wherein the feedback control system is further comprised of a sequencer feedback system.

16. The radio frequency power amplifier system of claim 14 wherein the sequencer is comprised of an asynchronous sequencer.

17. The radio frequency power amplifier system of claim 14 wherein the sequencer is comprised of a synchronous sequencer clocked from an external clock.

18. The radio frequency power amplifier system of claim 14 wherein the sequencer is asynchronous and further comprises a sequencer feedback system for coupling a portion of a sequencer output to a sequencer input.

19. The radio frequency power amplifier system of claim 1 wherein the signal cancellation system is configured to provide the error signal with a predetermined level of the input signal.

20. The radio frequency power amplifier system of claim 1, wherein the correction signal comprises a waveform with a quantized amplitude occurring at an average frequency in accordance with the radio frequency with timing determined by the feedback control system.

21. The radio frequency power amplifier system of claim i wherein the input signal is a base band input signal and the radio frequency power amplifier system further comprises complex mixers for frequency conversion of the input signal from a baseband frequency to the radio frequency and of the first feedback signal from the radio frequency to the baseband frequency.

22. A method of reducing distortion in a radio frequency power amplifier system, the method comprising:
amplifying in a forward path an input signal in a radio frequency power amplifier to provide an output signal at a radio frequency;
combining a reference signal that is based on the input signal and a first feedback signal that is based on the output signal to provide an error signal, the error signal having a reduced level of the input signal;
providing, in a feed back control system that is separate from the forward path, a correction signal, responsive to the error signal; and
using the correction signal to reduce distortion in the output signal.

23. The method of reducing distortion in a radio frequency power amplifier system of claim 22 wherein the combining a reference signal and a first feedback signal further comprises adjusting the phase and amplitude of the reference signal and the first feedback signal to reduce a level of the input signal that is present in the error signal.

24. The method of reducing distortion in a radio frequency power amplifier system of claim 23 wherein the adjusting the phase and amplitude of the reference signal and the first feedback signal reduces a level of the input signal to a predetermined level.

25. The method of reducing distortion in a radio frequency power amplifier system of claim 22 wherein the providing a correction signal further comprises providing an amplitude quantized correction signal with an average frequency in accordance with the radio frequency with timing determined by the feedback control system.

26. The method of reducing distortion in a radio frequency power amplifier system of claim 22 wherein the using the correction signal to reduce distortion in the output signal further comprises coupling the correction signal to an input of the radio frequency power amplifier.

27. The method of reducing distortion in a radio frequency power amplifier system of claim 22 wherein using the correction signal to reduce distortion further comprises coupling the correction signal to an output of the radio frequency power amplifier.
